(19) United States
(12) Patent Application Publication
(10) Pub. No.: US 2012/0187509 A1
(43) Pub. Date: Jul. 26, 2012

(54) Contact Arrangement For Establishing A Spaced, Electrically Conducting Connection Between Microstructured Components

(75) Inventors: Knut Gottfried, Grossruckerswalde (DE); Maik Wiemer, Limbach-Oberfrohna (DE); Axel Franke, Ditzingen (DE); Achim Trautmann, Leonberg (DE); Ando Feyh, Palo Alto, CA (US); Sonja Knies, Rutesheim (DE); Joerg Froemel, Chemnitz (DE)

(73) Assignee: Robert Bosch GmbH, Stuttgart (DE)

(21) Appl. No.: 13/120,994

(22) PCT Filed: Sep. 15, 2009
(86) PCT No.: PCT/EP2009/061921

§ 371 Date: Oct. 7, 2011

(30) Foreign Application Priority Data
Sep. 26, 2008 (DE) 10 2008 042 382.3

(51) Int. Cl. H01L 29/84; H01L 21/768; H01L 23/48

(52) U.S. Cl. 257/417; 257/774; 438/675; 257/E23.011; 257/E29.324; 257/E21.586

(57) ABSTRACT

A contact arrangement for establishing a spaced, electrically conducting connection between a first wafer and a second wafer includes an electrical connection contact, a passivation layer on the electrical connection contact, and a dielectric spacer layer arranged on the passivation layer, wherein the contact arrangement is arranged at least on one of the first wafer and the second wafer, wherein the contact arrangement comprises trenches at least partly filled with a first material capable of forming a metal-metal connection, wherein the trenches are continuous trenches from the dielectric spacer layer through the passivation layer as far as the electrical connection contact, and wherein the first material is arranged in the trenches from the electrical connection contact as far as the upper edge of the trenches.

### PRIOR ART

The present invention relates to a contact arrangement for establishing a spaced, electrically conducting connection between a first and a second microstructured component, comprising an electrical connection contact on the first microstructured component, a passivation layer on the connection contact and a dielectric spacer layer arranged on the passivation layer. It furthermore relates to a component arrangement, comprising first and second microstructured components connected to one another, wherein the first component comprises a first contact arrangement according to the invention and the second component has a first connection contact connected to the contact arrangement. It furthermore relates to a method for producing such a contact arrangement.

For the hermetic and electrical connection of an MEMS (microelectromechanical system) wafer to a second wafer, methods for eutectic bonding with different material combinations are known from the prior art. Examples of such eutectic connections are aluminum-germanium, gold-silicon, gold-tin and aluminum-silicon. Furthermore, arrangements for the vertical integration of MEMS components and evaluation circuits (application-specific integrated circuits, ASIC) are known which are based on a eutectic connection of the two constituents at the chip or wafer level.

When capping or encapsulating MEMS components, in particular inertial sensors, the necessary free mobility of the components is usually achieved by creating a cavity in the cap wafer in the region above the components. This region of the cap chip is then not suitable, or only suitable with high outlay, for accommodating further components, in particular an evaluation circuit for the sensor element.

Thus, US 2005/0166677 A1, for example, discloses a vertically integrated micromechanical (MEMS) arrangement, comprising: a) an MEMS subarrangement comprising a substantially planar frame and at least one MEMS element within said frame and flexible contact to the arrangement; b) a cover, which is connected to the frame by a first bond and is substantially parallel to the frame, and c) a base bonded to a surface of the frame and pointing away from the first substrate with a second bond. A gap between an electrode on the base and the MEMS element is produced lithographically. Precise control of the gap is provided and at least one MEMS element is fitted within a cavity.

Various possibilities for utilizing the cap wafer despite a cavity for the accommodation of the evaluation circuit are likewise known, but all have disadvantages. Thus, the evaluation circuit can be accommodated on that side of the cap wafer which faces away from the MEMS component. This is only possible by the electrical connections between sensor element and evaluation circuit either being led through the cap or being provided by means of wire bonding. In the first variant, the additional parasitic capacitances interfere in the case of capacitive evaluation of the MEMS components. The connections in the second alternative are complicated. For this purpose, the connections to the sensor wafer have to be freed by means of sawing, for example. Furthermore, the presence of open wire bonds here makes it more difficult to use the sensor as a “bare die”, that is to say without further packaging. It is also conceivable to accommodate the evaluation circuit on that side of the cap chip which faces the MEMS component, but alongside the cavity. However, this means a huge loss of area and hence additional costs.

It would therefore be desirable to have a possibility that allows a cap wafer, which can also comprise an ASIC, to be eutectically connected to an MEMS wafer in such a way that a well-defined distance is achieved and locally defined electrical connections can be realized between both wafers using simple methods of thin-film technology. It would furthermore be expedient if the flow effect of the liquid eutectic phase that always occurs in the case of eutectic bonding connections could be avoided. A misalignment during mounting could also be avoided as a result.

### DISCLOSURE OF THE INVENTION

The invention therefore proposes a contact arrangement for establishing a spaced, electrically conducting connection between a first wafer and a second wafer, wherein the contact arrangement comprises an electrical connection contact, a passivation layer on the connection contact and a dielectric spacer layer arranged on the passivation layer, and wherein the contact arrangement is arranged at least on one of the wafers.

The contact arrangement according to the invention is characterized in that the contact arrangement comprises trenches at least partly filled with a first material capable of forming a metal-metal connection, wherein the trenches are continuous trenches from the spacer layer through the passivation layer as far as the connection contact and in that the first material is arranged in the trenches from the connection contact as far as the upper edge of the trenches.

The contact arrangement according to the invention enables two wafers to be connected to one another in a spaced-apart fashion, such that a gap or a hollow space is obtained between the wafers. To put it another way, the present invention enables electrically conductive bonding connections with defined wafer spacing by means of plated-through spacer structures. The bonding connection can be embodied in hermetically impermeable fashion as necessary.

Microstructured components can be provided on the wafers and in a manner facing the gap or hollow space. The contact arrangement according to the invention can therefore be arranged both directly on a wafer and on a microstructured component that is situated on the wafer and faces the gap or hollow space. Electrical contact paths can be kept short in this way.

The present invention also includes a wafer comprising such a contact arrangement.

In this case, microstructured components within the meaning of the present invention are components whose functional structures have dimensions in the micrometers range. By way of example, said functional structures can have a length, height and/or width of ≧1 μm to ≧1000 μm. Components should be understood to mean both sensors and integrated circuits. Said integrated circuits can, for example, control the sensors or evaluate their signals. Application-specific integrated circuits can therefore also be involved.

The size, that is to say, in particular, length, height and/or width, of the contact arrangement according to the invention can likewise lie in the micrometers range.

One of the wafers from first wafer and second wafer is advantageously a cap wafer that can be used for the encapsulation of the two microstructured components. The cap wafer optionally comprises an ASIC.

What are capable of forming a metal-metal connection are, in particular, metals that form a eutectic with one another. In this way, fixed connections which can simultaneously function as electrical contacts can be produced at comparatively low temperatures.

The invention provides for the trenches in the spacer layers and passivation layers at least to be lined with such a material that can form a metal-metal connection. In this case, the upper edge of the trenches is the horizontal edge defined by the trench opening. As a result, it is possible to achieve the electrical contact externally through the elements forming the spacing. The form of the trenches themselves is initially not defined any further. The trenches can, for example, have an elongate shape or else be present in the form of holes. The trenches can also be arranged as an array composed of a multiplicity of holes.

The contact arrangement according to the invention has the advantage that no interventions in the process for producing the microelectromechanical systems are required for producing said contact arrangement. The contact arrangement can preferably be realized on the side of the cap, although the opposite case is also conceivable. Electrical connection contacts can be realized in a simple manner. Furthermore, flowing or compression of the liquid eutectic phase no longer occurs. As a result, no misalignment takes place and no bias is required, and so smaller structural sizes can also be achieved. The contact arrangement according to the invention can be applied to thick and thin material layers. A simple and exact setting of the distance between the microelectromechanical system and the capping wafer is furthermore possible.

In one embodiment of the contact arrangement according to the invention, the first material is applied as a layer on the surfaces of the inner sides of the trenches and the outer side of the spacer layer facing away from the connection contact. The thickness of said layer can lie, for example, in a range of ≧10 nm to ≦1000 nm, preferably of ≧100 nm to ≦500 nm. By virtue of the fact that the surface of the outer side of the spacer layer facing away from the connection contact is also covered with the first material layer, a large contact area can be produced with little use of material. In this way, it is possible to use expensive materials such as gold, for example.

In a further embodiment of the contact arrangement according to the invention, the first material fills the trenches and is not applied on the surface of the outer side of the spacer layer facing away from the connection contact. Such cases occur if the first material is deposited electrolytically. During the eutectic connection of a microelectromechanical element and a cap, by virtue of the correspondingly likewise significantly thicker eutectic zone that is liquid during the bonding process, compression or flowing thereof would normally occur. According to the invention, however, the dielectric spacer layer is used as lateral delimitation. No bonding layer remains on the spacer layer.

In a further embodiment of the contact arrangement according to the invention, the first material is selected from the group comprising gold, silicon, germanium, aluminum, copper, tin and/or indium. Gold and silicon, germanium and aluminum, and tin and indium can form eutectics with one another. Copper can be present as contact means on both microstructured components and the connection can be produced by means of thermocompression bonding. Furthermore, intermetallic phases can form between copper and tin as a result of diffusion.

The present invention furthermore relates to a component arrangement, comprising a first wafer and a second wafer connected to the first wafer, wherein the first wafer comprises a first microstructured component and the second wafer comprises a second microstructured component, wherein the first wafer comprises a first contact arrangement according to the invention, and wherein the second wafer comprises a first mating contact connected to the first contact arrangement and comprising a second material capable of the metal-metal connection, and wherein the first and the second material capable of the metal-metal connection furthermore form a connection together with one another.

In this way it is possible to construct spaced, electrically conducting connections between the wafers. The metal-metal connection between the first material and the second material is in this case advantageously a eutectic.

In one embodiment of the component arrangement, a first contact arrangement according to the invention circumferentially surrounds a section of the first wafer and a correspondingly formed first mating contact circumferentially surrounds a section of the second wafer. In this case, the circumferential first contact arrangement forms a connection together with the circumferential first mating contact with formation of an at least partly closed cavity. Furthermore, a second contact arrangement according to the invention is arranged within the circumferentially surrounded section on the first wafer, said second contact arrangement being connected to a first microstructured component within said section and being connected to a corresponding second mating contact on the second wafer.

The first contact arrangement according to the invention surrounds a first section of the first wafer circumferentially. This can be completely circumferential or circumferential in an interrupted manner. For this purpose, a corresponding mating contact is provided on the second wafer, said mating contact together with the contact arrangement establishing a spaced, electrically conducting connection. Furthermore, in this embodiment, a second contact arrangement and a second mating contact are present. As a result, the circumferentially surrounded microstructured component can be contact-connected directly and an electrically conducting and nevertheless spaced connection to the other wafer can be implemented.

In a further embodiment of the component arrangement according to the invention, the second component is a microelectromechanical component and the first component comprises an integrated circuit for control and/or signal processing for the microelectromechanical component, and the first component and the second component are furthermore present in a manner encapsulated by the connection between the first wafer and the second wafer.

The microelectromechanical component is advantageously an inertial sensor.

Encapsulated microsystems composed of sensors and associated control and evaluation electronics can be obtained in this way.

In a further embodiment of the component arrangement according to the invention, the connection between a contact arrangement according to the invention and a corresponding mating contact is achieved by means of a gold-silicon eutectic, an aluminum-germanium eutectic, a tin-indium eutectic, by means of solid-liquid interdiffusion (SLID) bonding of copper and tin or thermocompression bonding of copper. In this case, the connection method of solid-liquid interdiffusion bonding should be understood to mean that intermetallic Cu—Sn phases having a high melting point form as a result of the diffusion of copper and tin into the respective other metal.

The present invention furthermore relates to a method for producing a contact arrangement according to the invention, comprising the steps of providing a connection contact on a wafer, applying a passivation layer on the connection contact, structuring a dielectric spacer layer deposited on the passivation layer, wherein trenches are formed, and depositing a first material capable of forming a metal-metal connection at least partly into the trenches, wherein the trenches are structured as continuous trenches from the spacer layer as far as the connection contact, and wherein the first material is deposited in the trenches from the connection contact as far as the upper edge of the trenches.

The present invention is explained in more detail with reference to the following drawings, but without being restricted thereto. In the figures:

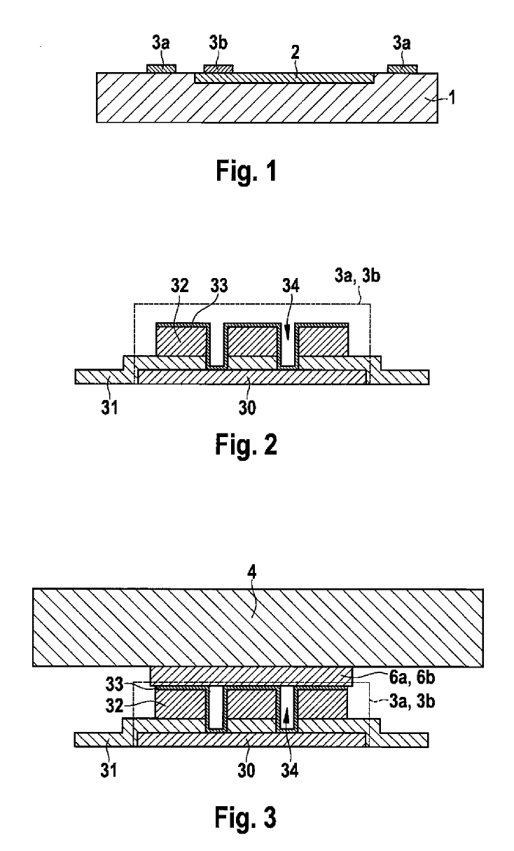

FIG. 1 shows a cap wafer,

FIG. 2 shows a detail illustration of a contact arrangement in accordance with a first variant,

FIG. 3 shows a detail illustration of a bonding connection realized in accordance with a first variant,

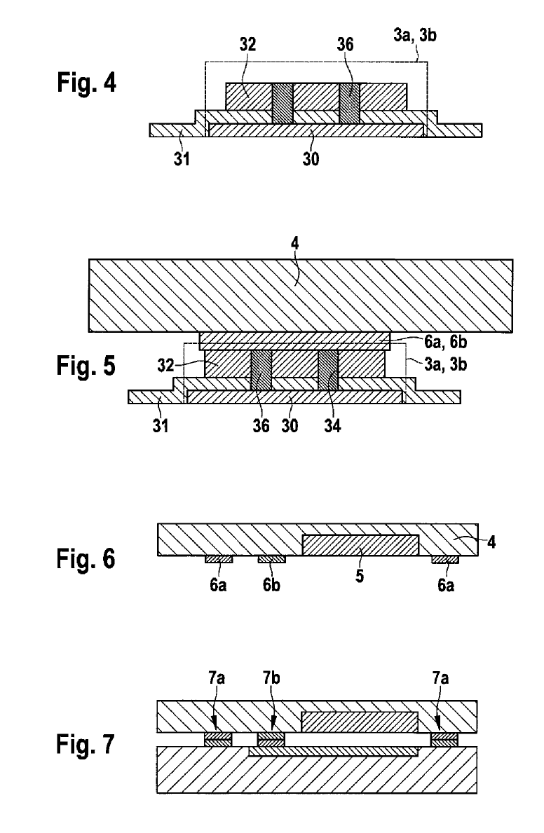

FIG. 4 shows a contact arrangement in accordance with a second variant,

FIG. 5 shows a detail illustration of a connection realized in accordance with a second variant,

FIG. 6 shows a microelectromechanical component,

FIG. 7 shows a finished wafer assemblage.

FIG. 1 shows a cap wafer 1, which comprises a first microstructured component 2. The component 2 is illustrated schematically here and can be, for example, an application-specific integrated circuit (ASIC). The wafer 1 comprises the first contact arrangement 3a, which functions as a bonding frame, and the second contact arrangement 3b. The first contact arrangement 3a is fitted directly on the wafer, and the second contact arrangement 3b on the first microstructured component 2.

FIG. 2 shows a detail illustration of the contact arrangements 3a and 3b according to the invention. In this case, an electrical connection contact 30, the material of which can be a metal such as aluminum or copper, which is used as a topmost wiring plane in the ASIC, for example, is provided with a passivation layer 31. The passivation layer 31 is usually a dielectric such as silicon dioxide or silicon nitride.

The dielectric spacer layer 32 is deposited on the passivation layer 31. Said spacer layer is preferably a silicon oxide having a thickness in the range of ≧2 μm to ≦10 μm. The spacer layer 32 is now provided with trenches 34 extending through as far as the metallic connection contact 30. A thin layer of metal 33 is subsequently deposited. The metal is one of the two bonding materials, preferably gold on an adhesion layer such as chromium or germanium. The layer 33 is likewise structured and a concluding second structuring of the spacer layer 32 then takes place, the actual bonding pad or the bonding frame being defined herein. This structuring stops on the passivation layer 31.

In the terminology of the present invention, therefore, here the first material 33 is applied as a layer on the surfaces of the inner sides of the trenches 34 and the outer side of the spacer layer 32 facing away from the connection contact 30.

FIG. 3 shows a detail view of a bonding connection between the cap wafer 1 from FIG. 1 (not illustrated) and a second wafer 4. Said second wafer 4 carries mating contacts 6a, 6b, which can form a metal-metal connection together with the metal layer 34 in the contact arrangement 3a, 3b. In this case, a eutectic bonding connection forms as a result of a suitable contact pressure and a temperature specific to the eutectic used.

FIG. 4 shows a contact arrangement 3a, 3b according to the invention for the case where the metal layer 36 is deposited in a significantly thicker fashion. This can take place by means of electrodeposition processes, for example. In this case, by virtue of the correspondingly likewise significantly thicker eutectic zone that is liquid during the bonding process, compression or flowing thereof normally occurs. In order to prevent this, the dielectric spacer layer 32 is used here as lateral delimitation.

As illustrated in FIG. 4, a metal layer 36 completely filling the trenches 34 is present rather than a thin metal layer 33. The bonding connection takes place only at the regions in which the metal 36 directly touches a mating contact of the complementary component. Lateral compression is therefore not possible.

In the terminology of the present invention, therefore, the first material 36 fills the trenches 34 and is not applied on the surface of the outer side of the spacer layer 32 facing away from the connection contact 30.

A detail illustration of the bonding connection achieved in accordance with the second variant from FIG. 4 is illustrated in FIG. 5. The contact arrangement 3a, 3b situated on the first wafer 1 (not illustrated) forms, via the metal layer 36 in the trenches 34, a metal-metal connection together with the mating contact 6a, 6b of the second wafer 4. In this case, a eutectic bonding connection forms as a result of a suitable contact pressure and a temperature specific to the eutectic used.

FIG. 6 schematically shows a component which comprises a microelectromechanical system (MEMS) and which can be connected to a further wafer by means of the contact arrangement according to the invention. In this case, the substrate or second wafer 4 is provided with the mating contacts 6a, 6b. A second microstructured component 5, which can be, for example, a sensor or specifically an inertial sensor, is illustrated schematically. The mating contacts 6a can be arranged around the component 5 circumferentially, for example in a ring-shaped manner. The mating contact 6b can advantageously be connected to the microstructured component 5.

FIG. 7 shows a finished wafer assemblage. The wafer arranged at the top is represented as in FIG. 6, and the wafer arranged at the bottom is represented as in FIG. 1. The connection between the two wafers is achieved by the bonding connection 7a running circumferentially in a ring-shaped manner and also by the connection 7b, wherein the connection 7b is electrically conductively connected to an application-specific integrated circuit for controlling, for example, a microstructured sensor or for evaluating the signals thereof. The connections 7a, 7b are obtained if contact arrangements 3a, 3b together with mating contacts 6a, 6b produce a metal-metal connection, that is to say generally form a eutectic.

As a result, therefore, a conducting bonding connection with defined wafer spacing was realized by means of plated-through spacer structures.

1. A contact arrangement for establishing a spaced, electrically conducting connection between a first wafer and a second wafer, the contact arrangement comprising:
an electrical connection contact;
a passivation layer on the electrical connection contact; and
a dielectric spacer layer arranged on the passivation layer,
wherein the contact arrangement is arranged at least on one of the first wafer and the second wafer,
wherein the contact arrangement comprises trenches at least partly filled with a first material capable of forming a metal-metal connection,
wherein the trenches are continuous trenches from the dielectric spacer layer through the passivation layer as far as the electrical connection contact, and
wherein the first material is arranged in the trenches from the electrical connection contact as far as the upper edge of the trenches.

2. The contact arrangement as claimed in claim 1, wherein the first material is applied as a layer on the surfaces of the inner sides of the trenches and the outer side of the spacer layer facing away from the electrical connection contact.

3. The contact arrangement as claimed in claim 1, wherein the first material fills the trenches and is not applied on the surface of the outer side of the dielectric spacer layer facing away from the electrical connection contact.

4. The contact arrangement as claimed in claim 1, wherein the first material is selected from the group comprising gold, silicon, germanium, aluminum, copper, tin, and indium.

5. A component arrangement, comprising:
a first wafer; and
a second wafer connected to the first wafer,
wherein the first wafer comprises a first microstructured component and the second wafer comprises a second microstructured component,
wherein the first wafer comprises a first contact arrangement including (i) a first electrical connection contact, (ii) a first passivation layer on the first electrical connection contact, and (iii) a first dielectric spacer layer arranged on the first passivation layer,
wherein the first contact arrangement comprises first trenches at least partly filled with a first material capable of forming a metal-metal connection,
wherein the first trenches are continuous trenches from the first dielectric spacer layer through the first passivation layer as far as the first electrical connection contact,
wherein the first material is arranged in the first trenches from the first electrical connection contact as far as the upper edge of the first trenches,
wherein the second wafer comprises a first mating contact connected to the first contact arrangement and comprising a second material capable of the metal-metal connection, and
wherein the first and the second material capable of the metal-metal connection furthermore form a connection together with one another.

6. The component arrangement as claimed in claim 5, wherein:
the first contact arrangement circumferentially surrounds a section of the first wafer,
a correspondingly formed first mating contact circumferentially surrounds a section of the second wafer,
the circumferential first contact arrangement forms a connection together with the circumferential first mating contact with formation of an at least partly closed cavity,
a second contact arrangement is furthermore arranged within the circumferentially surrounded section on the first wafer, said second contact arrangement being connected to a first microstructured component within said section and being connected to a corresponding second mating contact on the second wafer
said second contact arrangement including (i) a second electrical connection contact, (ii) a second passivation layer on the second electrical connection contact, and (iii) a second dielectric spacer layer arranged on the second passivation layer,
said second contact arrangement comprises second trenches at least partly filled with the second material capable of forming a metal-metal connection,
said second trenches are continuous trenches from the second dielectric spacer layer through the second passivation layer as far as the second electrical connection contact, and
said second material is arranged in the second trenches from the second electrical connection contact as far as the upper edge of the second trenches.

7. The component arrangement as claimed in claim 5, wherein the second component is a microelectromechanical component and the first component comprises an integrated circuit for one or more of control and signal processing for the microelectromechanical component, and wherein the first component and the second component are furthermore present in a manner encapsulated by the connection between the first wafer and the second wafer.

8. The component arrangement as claimed in claim 7, wherein the microelectromechanical component is an inertial sensor.

9. The component arrangement as claimed in claim 5, wherein the connection between the first contact arrangement and a corresponding mating contact is achieved by means of a gold-silicon eutectic, an aluminum-germanium eutectic, a tin-indium eutectic, by means of solid-liquid interdiffusion bonding of copper and tin or thermocompression bonding of copper.

10. A method for producing a contact arrangement, comprising:
providing a connection contact on a wafer;
applying a passivation layer on the connection contact;
structuring a dielectric spacer layer deposited on the passivation layer, wherein trenches are formed; and
depositing a first material capable of forming a metal-metal connection at least partly into the trenches,
wherein the trenches are structured as continuous trenches from the dielectric spacer layer as far as the connection contact, and
wherein the first material is deposited in the trenches from the connection contact as far as the upper edge of the trenches.
